(19) United States
(12) Patent Application Publication
(10) Pub. No.: US 2021/0328053 A1
(43) Pub. Date: Oct. 21, 2021

(54) SEMICONDUCTOR DEVICE AND MANUFACTURING METHOD THEREOF AND ELECTRONIC DEVICE INCLUDING THE SAME

(71) Applicant: INSTITUTE OF MICROELECTRONICS, CHINESE ACADEMY OF SCIENCES, Beijing (CN)

(72) Inventor: Huilong ZHU, Poughkeepsie, NY (US)

(21) Appl. No.: 17/226,919

(22) Filed: Apr. 9, 2021

(30) Foreign Application Priority Data
Apr. 17, 2020 (CN) 202010309178.X

(51) Int. Cl. H01L 29/78; H01L 29/66

(52) U.S. Cl. CPC H01L 29/7812; H01L 29/66666; H01L 29/66674; H01L 29/7827

(57) ABSTRACT

A semiconductor device that includes: a substrate; a first source/drain layer, a channel layer and a second source/drain layer stacked in sequence on the substrate in a vertical direction relative to the substrate, wherein the first source/drain layer includes a first source/drain region on an outer side of the substrate in a transverse direction, and a first body region on an inner side of the first source/drain region in the transverse direction; a gate stack surrounding a part of the channel layer; a back gate under the channel layer, wherein in a top view, the back gate, the first body region in the first source/drain region and the channel layer at least partially overlap; a back gate dielectric layer between the first source/drain layer and the back gate; and a back gate contact portion, the back gate contact portion is configured to apply a bias to the back gate.

### CROSS-REFERENCE TO RELATED APPLICATION

This application claims the benefit of Chinese Patent Application No. 202010309178.X filed on Apr. 17, 2020 in the China National Intellectual Property Administration, the whole disclosure of which is incorporated herein by reference.

### TECHNICAL FIELD

The present disclosure relates to the field of semiconductors, and in particular, to a vertical semiconductor device, a manufacturing method thereof and an electronic device including the same.

### BACKGROUND

In a horizontal element such as a metal oxide semiconductor field effect transistor (MOSFET), the source electrode, the gate electrode, and the drain electrode are arranged in a direction substantially parallel to the surface of the substrate. Due to this arrangement, the area occupied by the horizontal element is not easy to be further reduced or the manufacturing cost is not easy to be further reduced. Unlike this, in a vertical element, the source electrode, the gate electrode, and the drain electrode are arranged in a direction substantially perpendicular to the surface of the substrate. Therefore, compared to a horizontal element, a vertical element is easier to be reduced or the manufacturing cost is easier to reduce. A nanowire vertical gate-all-around field effect transistor (V-GAAFET) is one of the candidates for future high-performance elements.

However, for a vertical element such as a nanowire element, it is difficult to control, especially dynamically control the threshold voltage thereof, which is important for reducing the power consumption.

### SUMMARY

In view of this, it is at least a part of the purpose of the present disclosure to provide a vertical semiconductor device and a manufacturing method thereof, and an electronic device comprising the semiconductor device, the vertical semiconductor device is capable of controlling (or altering), especially dynamically controlling the threshold voltage.

According to one aspect of the present disclosure, a semiconductor device is provided, comprising: a substrate; a first source/drain layer, a channel layer and a second source/drain layer stacked in sequence on the substrate in a vertical direction relative to the substrate, wherein the first source/drain layer comprises a first source/drain region on an outer side of the substrate in a transverse direction, and a first body region on an inner sider of the first source/drain region in the transverse direction; a gate stack formed surrounding at least a part of the channel layer; a back gate under the channel layer, wherein in a top view, the back gate, the first body region in the first source/drain region and the channel layer at least partially overlap; a back gate dielectric layer between the first source/drain layer and the back gate; and a back gate contact portion, the back gate contact portion is used to apply a bias to the back gate.

According to another aspect of the present disclosure, a method of manufacturing a semiconductor device is provided, comprising: forming a back gate on one side of a substrate of an SOI substrate close to an insulating buried layer, the substrate comprising the substrate, the insulating layer and a semiconductor-on-insulator SOI layer; providing a stack of a first source/drain layer, a channel layer and a second source/drain layer on the SOI substrate; defining an active region overlapping the back gate in the stack, so that an outer periphery sidewall of the channel layer is recessed relative to outer periphery sidewalls of the first source/drain layer and the second source/drain layer; forming a first source/drain region and a second source/drain region in the first source/drain layer and the second source/drain layer, respectively, wherein the first source/drain region is formed in the first source/drain layer on an outer side of the SOI substrate in a transverse direction, the first source/drain layer further comprises a body region on an inner side of the first source/drain region in the transverse direction, the body region and the channel layer at least partially overlap; and forming a gate stack around at least a part of an outer periphery of the channel layer.

According to another aspect of the present disclosure, an electronic device is provided, comprising an integrated circuit formed by the semiconductor device.

According to the embodiments of the present disclosure, the back gate may affect the channel layer through the body region in the first source/drain layer. Thus, the threshold voltage may be adjust or altered. When applying a bias to the back gate, the threshold voltage may be altered dynamically according to the bias.

### BRIEF DESCRIPTION OF THE DRAWINGS

The aforementioned and other purposes, features and advantages of the present disclosure will become more apparent by the description to the embodiments of the present disclosure below with reference to the drawings, wherein in the drawings:

FIGS. 1-11 show schematic views of some stages of the process of manufacturing the semiconductor device according to the embodiments of the present disclosure,

wherein FIGS. 1, 2(a), 3(a), 4-8, 9(a), 10 and 11 are cross-sectional views;

FIGS. 2(b), 3(b) and 9(b) are top views, AA′ line in FIG. 2(b) shows the cut position of the cross section.

Throughout the drawings, the same or like reference numerals indicate the same or like components.

### DETAILED DESCRIPTION OF EMBODIMENTS

In the following, embodiments of the present disclosure will be described with reference to the drawings. However, it should be understood that, these descriptions are merely illustrative, and are not intended to limit the present disclosure. In addition, in the following specification, description of known structures and technologies are omitted to avoid unnecessarily confusing the concept of the present disclosure.

Various schematic structural views according to the embodiments of the present disclosure are shown in the drawings. These drawings are not drawn in scale, wherein for the purpose of clarity, some details are enlarged and some details may be omitted. Shapes of various regions, layers and their relative dimensional, positional relationship shown in the drawings are merely illustrative, in practice, there may be deviations due to manufacturing tolerances or technical limitations, and those skilled in the art may additionally design regions/layers with different shapes, sizes, relative positions according to actual needs.

In the context of the present disclosure, when a layer/device is referred to as being “on” another layer/device, the layer/device may be directly located on another layer/device, or there may be an intermediate layer/device between them. In addition, if a layer/device is located “on” another layer/device in one orientation, the layer/device may be “under” another layer/device when the orientation is reversed.

The vertical semiconductor device according to the embodiments of the present disclosure may include a first source/drain layer, a channel layer and a second source/drain layer stacked in sequence on the substrate. The layers may be adjacent to each other, of course there may be other semiconductor layers between the layers, such as a leakage suppression layer and an on-state current enhancement layer (semiconductor layer with the band gap larger or smaller than adjacent layers). Source/drain regions of the device may be formed in the first source/drain layer and the second source/drain layer, and a channel region of the device may be formed in the channel layer. According to the embodiments of the present disclosure, the semiconductor device may be a field effect transistor (FET). In the case of FET, the first source/drain region and the second source/drain region may have dopants of the same conductive type (for example, n type or p type). A conductive channel may be formed through the channel region between the first source/drain region and the second source/drain region respectively on two sides of the channel region. A gate stack is formed around at least a part of an outer periphery of the channel layer, and is capable of controlling the on/off of the channel region.

According to the embodiments of the present disclosure, the first source/drain layer may include the first source/drain region close to its outer periphery surface and a body region inside the first source/drain region (referred to as “the first body region”). The first body region may be unintentionally doped (relative to the first source/drain region) or lightly doped. In the case of doping, the doping type of the first body region may be opposite to the doping type of the first source/drain region. Under the first source/drain layer, a back gate dielectric layer and a back gate may be provided, the back gate dielectric layer is located between the first source/drain layer and the back gate. In the top view, the back gate, the first body region and the channel layer may at least partially overlap, thereby the electric field generated by the back gate is able to penetrate to first body region (for example, by depleting it) to affect the channel layer especially the channel region formed therein (and therefore affect the threshold voltage of the device). A bias may be applied to the back gate through a back gate contact portion, thereby the threshold voltage may be controlled dynamically.

The channel layer may be formed by a single crystal semiconductor material to improve the capacity of the device. Of course, the first source/drain layer and the second source/drain layer may also be formed of a single crystal semiconductor material. For example, the first source/drain layer may be the semiconductor substrate itself. In this case, the channel layer may be a semiconductor layer epitaxially grown on the channel layer, the second source/drain layer may be a semiconductor layer epitaxially grown on the substrate. Alternatively, the first source/drain layer may be a semiconductor layer epitaxially grown on the substrate. In this case, the channel layer may be a semiconductor layer epitaxially grown on the first source/drain layer, the second source/drain layer may be a semiconductor layer epitaxially grown on the channel layer. Due to the epitaxial growth, at least a part of adjacent layers may have a clear crystal interface.

An outer periphery sidewall of the channel layer may be recessed inwardly relative to sidewalls of the first source/drain layer, the second source/drain layer. In this way, an end portion of the gate stack formed may be embedded in the recess of the channel layer relative to the first source/drain layer and the second source/drain layer, the overlap with the source/drain region is reduced which facilitates reducing the parasitic capacitance between the gate and the source/drain.

To form the first body region in the first source/drain layer, the first source/drain region may be formed at a portion of the first source/drain layer close to the outer periphery surface. In general, the second source/drain region may be realized with the first source/drain region in the same process. Hence, the second source/drain region may also be formed at a portion of the second source/drain layer close to the outer periphery surface, thereby the second source/drain layer may also include a body region (referred to as “the second body region”) located inside the second source/drain region. The configuration of the second body region and the configuration of the first body region are basically the same or similar.

According to the embodiments of the present disclosure, the first source/drain region may not have direct physical contact with the channel layer. For example, the first source/drain region may be connected to the channel layer through the first body region, that is, the first body region may be extended beyond the outer periphery sidewall of the channel layer in a lateral direction. In this case, the gate stack may not only overlap with the channel layer to control the generation of the channel (similar to a vertical device) in the channel layer, but also overlap with the first body region to control the generation of the channel (similar to a planar device) in the first body region. The configuration of the second body region may be similar.

According to the embodiments of the present disclosure, the channel layer may have etching selectivity relative to the first source/drain layer and the second source/drain layer, for example, include different semiconductor materials. In this way, it is beneficial to process, for example, selectively etching the channel layer to make it recessed relative to the first source/drain layer and the second source/drain layer. In addition, the first source/drain layer and the second source/drain layer may include the same semiconductor material.

For example, such a semiconductor device may be manufactured as follows.

In order to realize the back gate configuration easily, a semiconductor-on-insulator (SOI) substrate may be used. The SOI substrate may include a base substrate, an insulating buried layer and an SOI layer. The back gate may be formed on a side close to the insulating buried layer in the base substrate, the insulating buried layer may be served as the back gate dielectric layer. A stack of the first source/drain layer, the channel layer and the second source/drain layer may be disposed on the SOI layer. As stated above, the SOI layer itself may be served as the first source/drain layer, and the stack may be formed by epitaxially growing the channel layer on the SOI layer and epitaxially growing the second source/drain layer on the channel layer. During the epitaxial growth, widths of various layers especially the channel layer may be controlled.

For the first source/drain layer, the channel layer and the second source/drain layer overlapped, an active region may be defined therein. For example, they may be selectively etched in sequence into required shapes. In general, the active region may be columnar (for example, cylindrical). In order to make the back gate affect the threshold voltage effectively, the active region may be overlapped with the back gate. The outer periphery sidewall of the channel layer may be recess inwardly relative to the first source/drain layer and the second source/drain layer so as to define a space containing the gate stack. For example, this may be realized by selective etching. In this case, the end portion of the gate stack may be embedded in the recess.

Source/drain regions may be formed in the first source/drain layer and the second source/drain layer. For example, this may be realized by doping the first source/drain layer and the second source/drain layer. For example, ion implantation, plasma doping may be performed. According to one advantageous embodiment, a sacrificial gate may be formed in the recess formed by the outer periphery sidewall of the channel layer relative to the outer periphery sidewalls of the first source/drain layer and the second source/drain layer, then a dopant source layer is formed on surfaces of the first source/drain layer and the second source/drain layer, and the dopant in the dopant source layer enters the active region via the first source/drain layer and the second source/drain layer by for example, annealing. The sacrificial gate may prevent the dopant in the dopant source layer from entering the channel layer. As stated above, to form the body region configuration, the source/drain region may be formed only in the surface portions of the first source/drain layer and the second source/drain layer.

The present disclosure may be present in various forms, some examples of which will be described in the following. In the following description, the selection of various materials is involved. the etching selectivity of material is further considered in the selection of the material in addition to the consideration of its functions (for example, the semiconductor material for forming the active region, the dielectric material for forming the electrical isolation). In the following description, the required etching selectivity may be or may be not pointed out. Those skilled in the art should understand that when a certain material layer is etched as mentioned below, if it is not mentioned that other layers are also etched or other layer are not shown to be etched in the drawings, this etching may be selective, and the material layer may have etching selectivity relative to other layers exposed to the same etching recipe.

FIGS. 1-11 show schematic views of some stages in the process of manufacturing the semiconductor device according to the embodiments of the present disclosure.

As shown in FIG. 1, a substrate 1001 is provided. Here, for ease of the formation of the back gate dielectric, the substrate 1001 may be a semiconductor-on-insulator (SOI) substrate. For example, the substrate 1001 may include a substrate 1001a such as Si, an insulating buried layer such as oxide (for example, silicon oxide) and an SOI layer such as Si. Of course, the present disclosure is not limited to this. Substrates in other forms may also be provided, for example, bulk semiconductor material substrate such as bulk Si substrate, compound semiconductor substrate such as SiGe substrate, etc. There are a plurality of ways to form a semiconductor-insulator-semiconductor structure.

In the substrate 1001a, the back gate 1003 may be formed by ion implantation. The conductive type of the dopant in the back gate 1003 and the conductive type of the device formed may be the same or may be opposite, the concentration of which is for example 5E18-1E21 cm⁻³. The back gate 1003 may be adjacent to the insulating buried layer 1001b, and the depth is for example, 5 nm-20 nm. In the example shown in FIG. 1, the back gate 1003 may be formed in a localized device region. For example, a photoresist (not shown) may be formed on the substrate 1001, and the photoresist may be patterned to expose the device region through photolithography, and the substrate 1001 may be ion implanted through the pattern photoresist to form the back gate 1003.

In addition, in order to electrically isolate the back gate 1003, an isolation well 1001w for the back gate 1003 may also be formed in the substrate 1001a (as shown by the dashed box in the drawing). The isolation well 1001w may also be formed by ion implanting the substrate 1001 through the same photoresist, and therefore may be located in substantially the same region as the back gate 1003. However, the depth of the isolation well 1001w may be greater than the depth of the back gate 1003, for example, about 20 nm-500 nm. The conductivity type of the dopant in the isolation well 1001w may be opposite to the conductivity type of the dopant in the back gate 1003, and the concentration may be lower than the concentration in the back gate 1003, for example, about 5E17-2E19 cm⁻³.

On the SOI layer 1001c, a channel layer 1005 and another semiconductor layer 1007 may be sequentially formed by, for example, epitaxial growth. Adjacent semiconductor layers may have etching selectivity with respect to each other. For example, the channel layer 1005 may include SiGe (the atomic percentage of Ge may be about 15%-30%) with a thickness of about 10-100 nm; the semiconductor layer 1007 may include Si with a thickness of about 20 nm-50 nm. Of course, the present disclosure is not limited to this.

The SOI layer 1001c may be doped by, for example, ion implantation to adjust characteristics of the body region formed therein. When the channel layer 1005 is grown, it may be doped in-situ to adjust the threshold voltage (Vₜ) of the device. When the semiconductor layer 1007 is grown, it may be doped in situ to adjust characteristics of the body region formed therein.

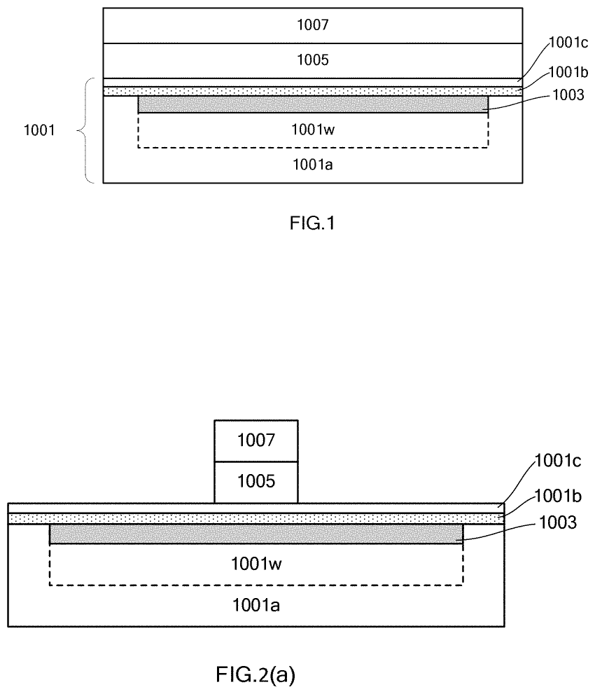

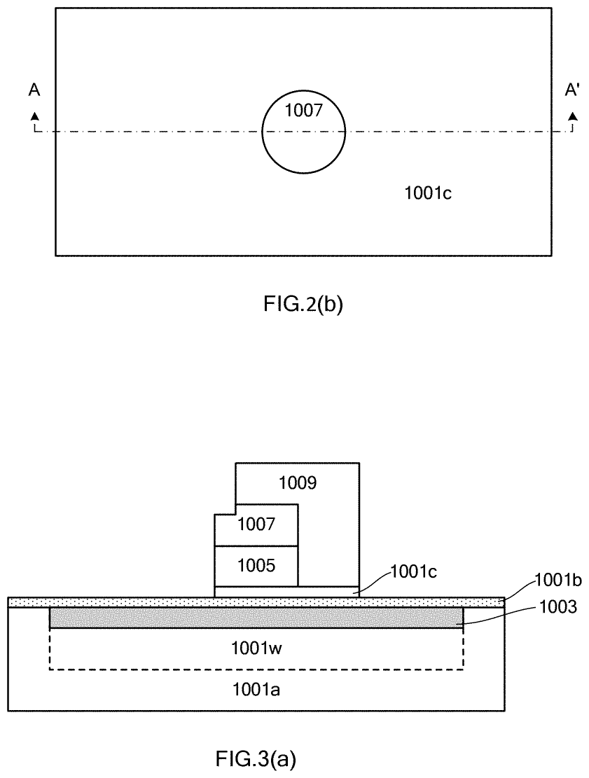

Then, the active region of the device may be defined. For example, as shown in FIGS. 2(a) and 2(b), a photoresist (not shown) may be formed on the substrate 1001 on which the channel layer 1005 and the semiconductor layer 1007 are formed, and the photoresist is patterned to the desired shape (in this example, roughly circular) through photolithography, and the patterned photoresist is used as a mask to sequentially selectively etch (such as reactive ion etching (RIE)) the semiconductor layer 1007 and the channel layer 1005. ME may be performed in a vertical direction (a direction substantially perpendicular to the surface of the substrate), for example, and may be stopped at the SOI layer 1001c.

Here, the roughly circular photoresist will result in the formation of a nanowire device. However, the present disclosure is not limited to this. For example, the photoresist can be patterned into a rectangle or a square shape, so that a nanosheet device may be formed. Of course, the shape of the photoresist is not limited to this.

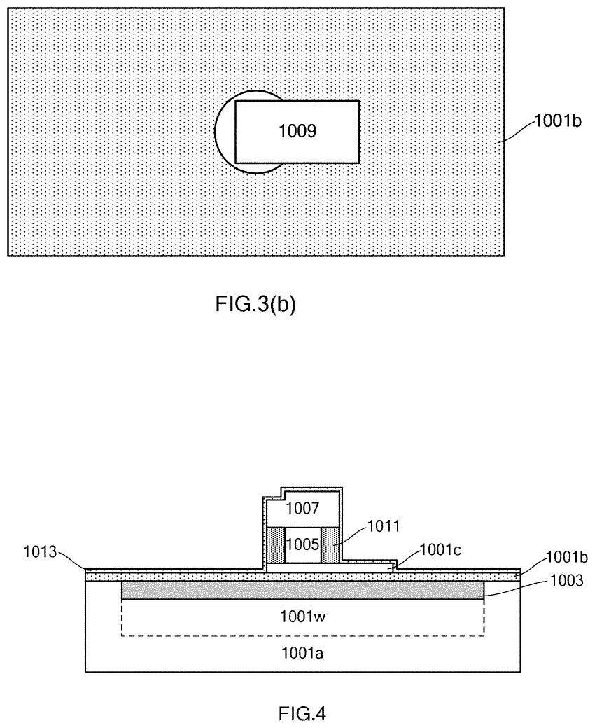

In addition, as shown in FIGS. 3(a) and 3(b), a photoresist 1009 may be formed on the structure shown in FIGS. 2(a) and 2(b), and it is patterned into shielding a certain region (for example, a bar-shaped area, so as to subsequently form a landing pad to a contact portion of the source/drain region) in a portion of the SOI layer 1001c beyond the above channel layer 1005 and the above semiconductor layer 1007. The photoresist 1009 may be used as a mask to selectively etch, such as ME the SOI layer 1001c. Likewise, ME may be performed in the vertical direction. Thus, in addition to the portion under the channel layer 1005 and the semiconductor layer 1007, the SOI layer 1001c may also include a (for example, strip-shaped) portion extending beyond the channel layer 1005 and the semiconductor layer 1007. After that, the photoresist 1009 may be removed.

Thus, the SOI layer 1001c, the channel layer 1005, and the semiconductor layer 1007 may be substantially columnar (in this example, substantially cylindrical), except that the SOI layer 1001c includes an extension portion.

In order to form a gate stack self-aligned to the channel layer 1005, an outer periphery sidewall of the channel layer 1005 may be recessed with respect to outer peripheral sidewalls of the SOI layer 1001c and the semiconductor layer 1007 (in this example, recessed in a transverse direction substantially parallel to substrate surface). For example, this may be achieved by further selectively etching the channel layer 1005 (in this example, SiGe) relative to the SOI layer 1001c and the semiconductor layer 1007 (in this example, Si). In order to control the etching depth, the etching of the channel layer 1005 may be performed by atomic layer etching (ALE). The etching depth surrounding the periphery of the channel layer 1005 may be approximately the same. That is, after etching, the channel layer 1005 may remain substantially central-aligned with the semiconductor layer 1007, and the shape remains substantially the same (but shrunk).

In this way, the active region (the SOI layer 1001c, the channel layer 1005, and the semiconductor layer 1007) of the semiconductor device is defined. In this example, the active region is roughly columnar. In the active region, the outer periphery sidewall of the channel layer 1005 is recessed with respect to the outer peripheral sidewalls of the SOI layer 1001c and the semiconductor layer 1007.

In the recess of the channel layer 1005 formed with respect to the SOI layer 1001c and the semiconductor layer 1007, the gate stack will be formed subsequently. In order to prevent subsequent processing from affecting the channel layer 1005 or leaving unnecessary material in the recess to affect the formation of the subsequent gate stack, a material layer may be filled in the recess to occupy the space of the gate stack (therefore, this material layer may be called “sacrificial gate”). For example, this may be done by depositing nitride and then etching back (such as ME) the deposited nitride. ME may be performed in the vertical direction, so that the nitride may only remain in the recess to form the sacrificial gate 1011, as shown in FIG. 4. In this case, the sacrificial gate 1011 may substantially fulfill the aforementioned recess.

Next, source/drain regions may be formed in the SOI layer 1001c and the semiconductor layer 1007. This may be formed by doping the SOI layer 1001c and the semiconductor layer 1007. For example, this may be done as follows.

For example, as shown in FIG. 4, a dopant source layer 1013 may be formed on the substrate defining the active region. For example, the dopant source layer 1013 may include an oxide such as silicon oxide, which contains a dopant. For a n-type device, n-type dopants may be included; for a p-type device, p-type dopants may be included. Here, the dopant source layer 1013 may be a thin film, which may be substantially conformally deposited on the surface of the active region by, for example, chemical vapor deposition (CVD) or atomic layer deposition (ALD).

Next, as shown in FIG. 5, the dopant contained in the dopant source layer 1013 may be brought into the active region, particularly the SOI layer 1001c and the semiconductor layer 1007, by annealing, for example, to form a doped region therein, as shown in the shaded portion in the drawing. More specifically, one of the source/drain regions S/D1 may be formed in the SOI layer 1001c, and the other source/drain region S/D2 may be formed in the semiconductor layer 1007. After that, the dopant source layer 1013 may be removed.

Here, the degree to which the dopant brought into the SOI layer 1001c and the semiconductor layer 1007 may be controlled so that the source/drain regions S/D1 and S/D2 do not reach the channel layer 1005. More specifically, the degree of diffusion of the dopant in the transverse direction may be less than the degree of recession of the channel layer 1005 relative to the SOI layer 1001c and the semiconductor layer 1007 in the transverse direction. For example, in FIG. 5, the sidewall of the channel layer 1005 and the boundary of the source/drain region may be separated by a certain distance t. Thus, the source/drain regions S/D1 and S/D2 may be respectively formed in the portions of the SOI layer 1001c and the semiconductor layer 1007 close to the surfaces, respectively, and inner portions of the SOI layer 1001c and the semiconductor layer 1007 may still maintain the same doping characteristics (for example, unintentional doping or low doping) as before and may form body regions. The conductivity type of the dopant in the body region (if doped) may be opposite to the conductivity type of the source/drain regions S/D1 and S/D2. The body region extends beyond the aforementioned distance t of the sidewall of the channel layer 1005 in the transverse direction.

In the above example, the source/drain regions are formed by driving in the dopant from the dopant source layer into the active region, however, the present disclosure is not limited thereto. For example, the source/drain regions may be formed by ion implantation, plasma doping (for example, conformal doping along the surface of the structure in FIG. 4), etc.

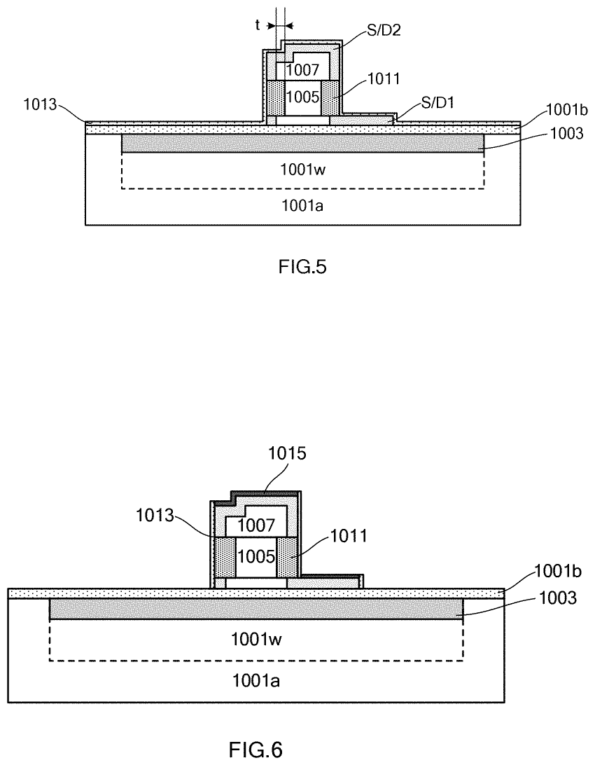

To reduce the contact resistance, silicide may also be formed on the surfaces of the source/drain regions. Here, in order to avoid undesired electrical contact between the silicide and the gate conductor layer formed later, the silicide may be formed only on the top surfaces of the source/drain region. For example, as shown in FIG. 6, a protective layer may be formed on the sidewalls of the source/drain regions through a spacer formation process. Here, the protective layer may be formed by anisotropic etching (such as RIE in the vertical direction) the dopant source layer 1013. Thus, the top surfaces of the source/drain regions S/D1 and S/D2 may be exposed. A metal layer such as NiPt (the content of Pt is about 1-10%) may be formed on the top surfaces of the source/drain regions S/D1 and S/D2, for example, by deposition, and annealing is performed at a temperature of about 200° C.-600° C., so that the metal reacts with the semiconductor devices in the source/drain regions S/D1 and S/D2 to generate a silicide (here, SiNiPt) layer 1015. After that, unreacted remaining metal may be removed, and the dopant source layer 1013 served as the current protective layer may be removed.

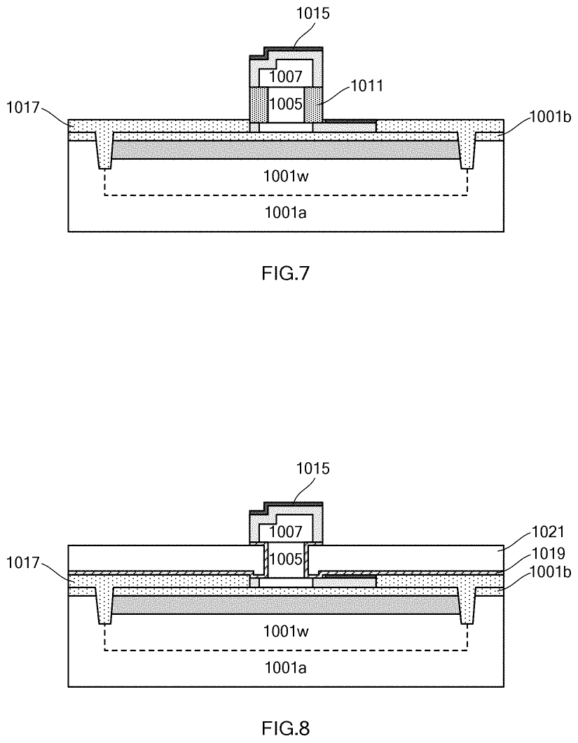

According to the embodiments of the present disclosure, shallow trench isolation (STI) may also be provided to limit the range of the device. For example, as shown in FIG. 7, photolithography may be used to form trenches defining the range of the device in the insulating buried layer 1001b and the substrate 1001a, and the trenches may be filled with insulating material such as oxides to form STIs. The range defined by the STI may be approximately the same as the range of the previous range of the isolation well 1001w or the back gate 1003. Here, the bottom of the STI may be lower than the bottom surface of the back gate 1003 to suppress leakage current. The filling of the trench may be achieved by deposition and then etch back. Before the etching back, the deposited oxide may be planarized, such as chemical mechanical polishing (CMP). During the etching back, a certain thickness of insulating material may be left on the insulating buried layer 1001b, thereby forming an isolation layer together with the STI (denoted as 1017 together with the STI). The isolation layer may surround the active region to realize electrical isolation. Here, the top surface of the isolation layer may be close to the interface between the channel layer 1005 and the SOI layer 1001c.

Next, a replacement gate process may be performed.

For example, as shown in FIG. 8, the sacrificial gate 1011 may be removed to release the space in the recess. For example, the sacrificial gate 1011 (nitride) may be selectively etched with respect to the isolation layer 1017 (oxide) and the SOI layer 1001c, the semiconductor layer 1007 (Si) and the channel layer 1005 (SiGe). The gate stack may be formed in the released recess. Specifically, the gate dielectric layer 1019 and the gate conductor layer 1021 may be deposited sequentially, and the deposited gate conductor layer 1021 may be etched back so that the top surface of the portion outside the recess is not higher than and preferably lower than the top surface of the channel layer 1005. Before the etch back, the gate conductor layer may be planarized, such as CMP. For example, the gate dielectric layer 1019 may include a high-K gate dielectric such as HfO2 with a thickness of about 1 nm-5 nm; the gate conductor layer 1021 may include a metal gate conductor, such as one or more of Ti, Al, La, and Ru. Before forming the gate dielectric layer 1019, an oxide interface layer of, for example, about 0.5 nm-2 nm may also be formed. In the example of FIG. 8, after the gate conductor layer 1021 is etched back, the gate dielectric layer 1019 is also selectively etched such as RIE, so that the portion covered by the gate conductor layer 1021 is remained.

In this way, an end portion of the gate stack may be embedded into the recess, so as to overlap the entire height of the channel layer 1005.

In addition, depending on the position of the top surface of the isolation layer 1017, the gate stack may have a certain overlap with the underlying source/drain region S/D1 in the vertical direction (for example, in the case of the top surface of the isolation layer 1017 is lower than the interface between the channel layer 1005 and the SOI layer 1001c), this will increase the parasitic capacitance between the gate and the source/drain. Therefore, preferably, the top surface of the isolation layer 1017 is not lower than the interface between the channel layer 1005 and the SOI layer 1001c, for example, it may be located between the top surface and the bottom surface of the channel layer 1005.

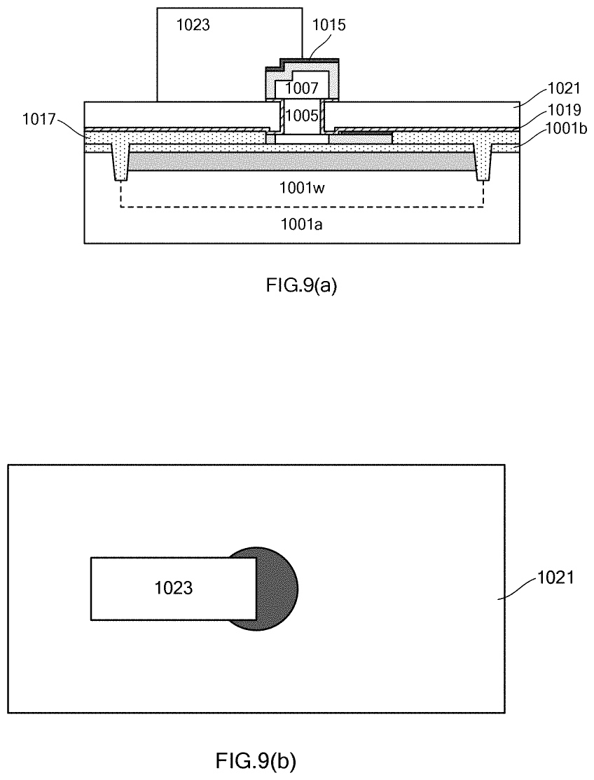

Next, the shape of the gate stack may be adjusted to facilitate subsequent interconnection manufactures. For example, as shown in FIGS. 9(a) and 9(b), a photoresist 1023 may be formed. The photoresist 1023 may be patterned, for example, by photolithography to cover a portion (in this example, the portion on the left side of the drawing to avoid interfering with the landing pad of the contact portion of the source/drain region S/D1) of the gate stack exposed outside the recess.

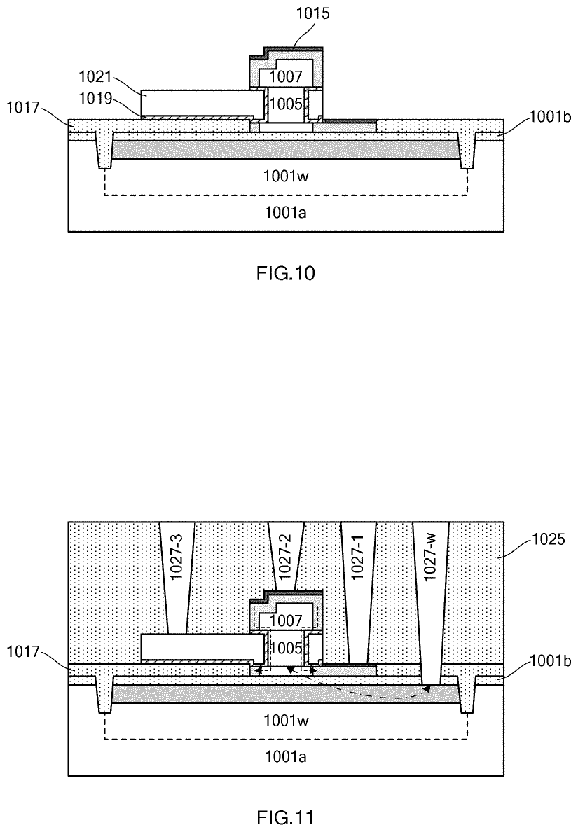

Then, as shown in FIG. 10, the photoresist 1023 may be used as a mask to selectively etch (such as RIE) the gate conductor layer 1021. In this way, except for the portion of the gate conductor layer 1021 remaining in the recess, the portion shielded by the photoresist 1023 is remained. This portion may be used as the landing pad for the contact portion to the gate conductor layer. In addition, the gate dielectric layer 1019 may also be selectively etched such as RIE. After that, the photoresist 1023 may be removed.

Then, as shown in FIG. 11, an interlayer dielectric layer 1025 may be formed on the structure shown in FIG. 10. For example, an oxide may be deposited and planarized, such as CMP, to form the interlayer dielectric layer 1025. In the interlayer dielectric layer 1025, a contact portion 1027-1 to the source/drain region S/D1, a contact portion 1027-2 to the source/drain region S/D2, and a contact portion 1027-3 to the gate conductor layer 1021 may be formed. In addition, a contact portion 1027-w to the back gate 1003 may also be formed. These contact portions may be formed by etching holes in the interlayer dielectric layer 1027, the isolation layer 1017, and the insulating buried layer 1001b, and filling them with conductive material such as metal (for example, tungsten). Before depositing the metal, a diffusion barrier layer such as TiN may be formed first.

As shown by the dashed arrow in the drawing, current may flow from one source/drain region (for example, S/D2) to the other source/drain region (for example, S/D1) (or, the current may flow in the opposite direction). In this example, the channel may be formed not only at the vertical sidewall of the channel layer 1005 (similar to a vertical device), but also at a portion of the horizontal surface of the SOI layer 100c and the semiconductor layer 1007 (similar to a planar device). The gate stack not only overlaps with the sidewall of the channel layer 1005 (so that the channel therein may be controlled), but also overlaps with the body regions in the SOI layer 100c and the semiconductor layer 1007 (thereby the channel therein may be controlled). That is, the semiconductor device according to this embodiment may be equivalent to a combination of a vertical type device and a planar type device. Of course, the present disclosure is not limited to this. Depending on the range of the source/drain regions, for example, when t≤0 as shown in FIG. 5 (t<0 means that the source/drain regions and the channel layer overlap each other), the channel may also be formed only at the vertical side walls of the channel layer 1005.

In the central portion of the SOI layer 1001c, for example, a body region may be formed inside the source/drain region S/D1. As shown by the dotted arrow in the drawing, through the contact portion 1027-w, a potential may be applied to the back gate 1003, and the electric field generated by the back gate 1003 may penetrate the body region in the SOI layer 1001c (for example, make it deplete) to affect the channel layer 1005 and therefore affect the threshold voltage of the device. The threshold voltage may be dynamically adjusted by dynamically adjusting the applied potential. Of course, in the central portion of the semiconductor layer 1007, for example, a body region may be formed inside the source/drain region S/D2. The body region may have a certain (light) doping. Thus, the channel layer 1005 may form an ohmic contact with the body region in the SOI layer 1001c and/or the semiconductor layer 1007. Alternatively, the SOI layer 1001c and/or the semiconductor layer 1007 may have a higher concentration of electrons or holes of the intrinsic semiconductor, so that the body region may be undoped.

Since the gate conductor layer 1021 extends beyond the outer periphery of the active region on the left side, the contact portion 1027-3 thereto may be easily formed. In addition, since the SOI layer 1001c extends beyond the active region on the right side, the contact portion 1027-1 thereto may be easily formed.

As shown in FIG. 11, the semiconductor device according to this embodiment includes the SOI layer 1001c, the channel layer 1003, and the semiconductor layer 1007 overlapped in the vertical direction. The source/drain region S/D-1 is formed in the SOI layer 1001c, and the source/drain region S/D-2 is formed in the semiconductor layer 1007. The channel layer 1005 is recessed transversely, the gate stack (1019/1021) is formed surrounding the outer periphery of the channel layer 1005, and the end portion thereof is embedded into the recess. The back gate 1003 is disposed under the active region, and is opposite to the active region through the insulating buried layer 1001b.

The semiconductor device according to the embodiments of the present disclosure may be applied to various electronic devices. For example, by integrating a plurality of such semiconductor devices and other devices (for example, other forms of transistors, etc.), it is possible to form an integrated circuit (IC) and thereby constructing an electronic device. Therefore, the present disclosure further provides an electronic device including the above-mentioned semiconductor device. The electronic device may also include components such as a display screen matched with the integrated circuit and a wireless transceiver matched with the integrated circuit. Such electronic devices include smart phones, computers, tablet computers (PCs), artificial intelligence, wearable devices, portable power supplies, etc.

According to the embodiments of the present disclosure, a method for manufacturing a system on chip (SoC) is also provided. The method may include the above-mentioned method of manufacturing a semiconductor device. Specifically, a variety of devices may be integrated on the chip, at least some of which are manufactured according to the method of the present disclosure. In the above description, technical details such as patterning and etching, etc. of each layer have not been described in detail. However, those skilled in the art should understand that various technical means may be used to form layers, regions, etc. of desired shapes. In addition, in order to form the same structure, those skilled in the art may also design a method that is not completely the same as the method described above. In addition, although the various embodiments are described above respectively, this does not mean that the measure in each embodiment may not be advantageously used in combination.

The embodiments of the present disclosure have been described above. However, these embodiments are merely for illustrative purposes, and are not intended to limit the scope of the present disclosure. The scope of the present disclosure is defined by the appended claims and their equivalents. Without departing from the scope of the present disclosure, those skilled in the art may make various substitutions and modifications, and these substitutions and modifications should fall within the scope of the present disclosure.

What is claimed is:

1. A semiconductor device, comprising:
a substrate;
a first source/drain layer, a channel layer and a second source/drain layer stacked in sequence on the substrate in a vertical direction relative to the substrate, wherein the first source/drain layer comprises a first source/drain region on an outer side of the substrate in a transverse direction, and a first body region on an inner sider of the first source/drain region in the transverse direction;
a gate stack surrounding at least a part of the channel layer;
a back gate under the channel layer, wherein in a top view, the back gate, the first body region in the first source/drain region and the channel layer at least partially overlap;
a back gate dielectric layer between the first source/drain layer and the back gate; and
a back gate contact portion, wherein the back gate contact portion is configured to apply a bias to the back gate.

2. The semiconductor device according to claim 1, wherein the first body region extends beyond an outer periphery sidewall of the channel layer in the transverse direction, and the gate stack comprises a portion overlapping the first body region.

3. The semiconductor device according to claim 1, wherein the first body region is configured to be capable of being depleted by an electric field generated by the back gate due to the applied bias.

4. The semiconductor device according to claim 1, wherein the first source/drain region is a heavily doped region in the first source/drain layer, and the first body region is a non-doping region or a lightly doped region in the first source/drain layer.

5. The semiconductor device according to claim 4, wherein a doping type of the first body region and a doping type of the first source/drain region are opposite.

6. The semiconductor device according to claim 1, wherein the first body region and the channel layer form an ohmic contact.

7. The semiconductor device according to claim 1, wherein the second source/drain layer comprises a second source/drain region on an outer side in the transverse direction and a second body region on an inner side of the second source/drain region in the transverse direction, and the second body region and the channel layer at least partially overlap.

8. The semiconductor device according to claim 1, wherein the second body region extends beyond an outer periphery sidewall of the channel layer, and the gate stack comprises a portion overlapping the second body region.

9. The semiconductor device according to claim 7, wherein the second source/drain region is a heavily doped region in the second source/drain region, and the second body region is a non-doping region or a light doped region in the second source/drain layer.

10. The semiconductor device according to claim 9, wherein a doping type of the second body region and a doping type of the second source/drain region are opposite.

11. The semiconductor device according to claim 10, wherein the second body region and the channel region form an ohmic contact.

12. The semiconductor device according to claim 1, wherein the substrate comprises an SOI substrate, the SOI substrate comprises a base substrate, an insulating buried layer and an SOI layer, and the back gate comprises a well formed in the base substrate, the back gate dielectric layer comprises a portion of the insulating buried layer, and the first source/drain layer comprises a portion of the SOI layer.

13. The semiconductor device according to claim 1, wherein the outer periphery sidewall of the channel layer is recessed inwardly relative to respective outer periphery sidewalls of the first source/drain layer and the second source/drain layer.

14. The semiconductor device according to claim 13, wherein an end portion on a side of the gate stack close to the channel layer is embedded in the recess of the outer periphery sidewall of the channel layer relative to the outer periphery sidewalls of the first source/drain layer and the second source/drain layer.

15. The semiconductor device according to claim 1, wherein the channel layer comprises a single crystal semiconductor material.

16. A method of manufacturing a semiconductor device, comprising:
forming a back gate on a side of a base substrate of an SOI substrate close to an insulating buried layer, the SOI substrate comprising the base substrate, the insulating buried layer and an SOI layer;
providing a stack of a first source/drain layer, a channel layer and a second source/drain layer on the SOI substrate;
defining an active region overlapping the back gate in the stack, so that an outer periphery sidewall of the channel layer is recessed relative to outer periphery sidewalls of the first source/drain layer and the second source/drain layer;
forming a first source/drain region and a second source/drain region in the first source/drain layer and the second source/drain layer, respectively, wherein the first source/drain region is formed in the first source/drain layer on an outer side of the SOI substrate in a transverse direction, the first source/drain layer further comprises a body region on an inner side of the first source/drain region in the transverse direction, the body region and the channel layer at least partially overlap; and
forming a gate stack around at least a part of an outer periphery of the channel layer.

17. The method according to claim 16, wherein providing the first source/drain layer comprises:
providing the first source/drain layer from the SOI layer of the SOI substrate.

18. The method according to claim 16, wherein forming the back gate comprises:
forming a well in the base substrate by ion implantation.

19. The method according to claim 16, wherein forming the first source/drain region and the second source/drain region comprises:
forming a sacrificial gate in the recess of the outer periphery sidewall of the channel layer formed relative to the outer periphery sidewalls of the first source/drain layer and the second source/drain layer;
forming a dopant source layer on a surface of the first source/drain layer and the second source/drain layer; and
driving dopants in the dopant source layer into the first source/drain layer and the second source/drain layer.

20. The method according to claim 19, further comprising: controlling an extent of the dopant entering into the first source/drain layer and the second source/drain layer to be smaller than a recessing extent of the recess of the outer periphery sidewall of the channel layer relative to the outer periphery sidewalls of the first source/drain layer and the second source/drain layer.

21. The method according to claim 19, further comprising:
forming an isolation layer around the active region on the substrate, wherein a top surface of the isolation layer is close to an interface between the channel layer and the first source/drain layer, or located between a top surface and a bottom surface of the channel layer.

22. The method according to claim 21, wherein forming the gate stack comprises:
removing the sacrificial gate;
forming a gate dielectric layer and a gate conductor layer in sequence on the isolation layer; and
etching back the gate conductor layer, so that a top surface of a portion of the gate conductor layer outside the recess is lower than the top surface of the channel layer.

23. The method according to claim 19, further comprising: forming a silicide on the surface of the first source/drain layer and the second source/drain layer.

24. The method according to claim 16, wherein the stack is provided by epitaxial growth.

25. The method according to claim 16, further comprising:
forming a back gate contact portion to the back gate.

26. An electronic device, comprising an integrated circuit formed by the semiconductor device according to claim 1.

27. The electronic device according to claim 26, further comprising: a display matched with the integrated circuit and a wireless transceiver matched with the integrated circuit.

28. The electronic device according to claim 26, wherein the electronic device comprises smart phones, computers, tablet computer, artificial intelligence devices, wearable devices or portable power sources.
